(19) United States
(12) Patent Application Publication
(10) Pub. No.: US 2024/0357741 A1
(43) Pub. Date: Oct. 24, 2024

(54) PRINTED CIRCUIT BOARD AND ELECTRONIC DEVICE INCLUDING THE SAME

(71) Applicant: Samsung Electronics Co., Ltd., Suwon-si (KR)

(72) Inventors: Yeonkyung CHUNG, Suwon-si (KR); Jinyong PARK, Suwon-si (KR); Chulwoo PARK, Suwon-si (KR); Yongjae SONG, Suwon-si (KR); Sangwon HA, Suwon-si (KR)

(21) Appl. No.: 18/640,555

(22) Filed: Apr. 19, 2024

Related U.S. Application Data
(63) Continuation of application No. PCT/KR2024/005353, filed on Apr. 19, 2024.

(30) Foreign Application Priority Data
Apr. 19, 2023 (KR) 10-2023-0051627
Oct. 10, 2023 (KR) 10-2023-0134523

(51) Int. Cl. H05K 1/03

(52) U.S. Cl. CPC H05K 1/036; H05K 2201/0191; H05K 2201/0209

(57) ABSTRACT

An electronic device according to an embodiment of the disclosure may comprise: a housing and a printed circuit board disposed in the housing and comprising an alternately stacked plurality of insulation layers and plurality of conductive layers. The plurality of insulation layers may include at least one first insulation layer and at least one second insulation layer. The at least one first insulation layer may include a first insulator including a resin having a Tg value of 200 degrees or more and a filler having a content of 50% to 70%. The at least one second insulation layer may include a second insulator including a glass fiber.

### CROSS-REFERENCE TO RELATED APPLICATIONS

This application is a continuation of International Application No. PCT/KR2024/005353 designating the United States, filed on Apr. 19, 2024, in the Korean Intellectual Property Receiving Office and claiming priority to Korean Patent Application Nos. 10-2023-0051627, filed on Apr. 19, 2023, and 10-2023-0134523, filed on Oct. 10, 2023, in the Korean Intellectual Property Office, the disclosures of each of which are incorporated by reference herein in their entireties.

### BACKGROUND

### Field

The disclosure relates to a printed circuit board and an electronic device including the same.

### Description of Related Art

Advancing information communication technologies and semiconductor technologies accelerate the spread and use of various electronic devices. In particular, recent electronic devices are being developed to carry out communication while carried on.

The term “electronic device” may refer, for example, to a device performing a particular function according to its equipped program, such as a home appliance, an electronic scheduler, a portable multimedia player, a mobile communication terminal, a tablet PC, a video/sound device, a desktop PC or laptop computer, a navigation for automobile, etc. For example, the electronic devices may output stored information as voices or images. As electronic devices are highly integrated, and high-speed, high-volume wireless communication becomes commonplace, an electronic device, such as a mobile communication terminal, is recently being equipped with various functions. For example, an electronic device comes with the integrated functionality, including an entertainment function, such as playing video games, a multimedia function, such as replaying music/videos, a communication and security function for mobile banking, and a scheduling or e-wallet function. These electronic devices have been downsized to be conveniently carried by users. As the carrying and use of compact and slim mobile devices, e.g., smartphones, become commonplace, users demand diversified, high-class exterior design for mobile devices.

The above-described information may be provided as related art for the purpose of helping understanding of the disclosure. No claim or determination is made as to whether any of the foregoing is applicable as background art in relation to the disclosure.

### SUMMARY

An electronic device according to an example embodiment of the disclosure may comprise: a housing and a printed circuit board disposed in the housing and including an alternately stacked plurality of insulation layers and plurality of conductive layers. The plurality of insulation layers may include at least one first insulation layer and at least one second insulation layer. The at least one first insulation layer may include a first insulator including a resin having a Tg value of 200 degrees or more and a filler having a content of 50% to 70%. The at least one second insulation layer may include a second insulator including a glass fiber.

A printed circuit board according to an example embodiment of the disclosure may comprise: an alternately stacked plurality of insulation layers and plurality of conductive layers. The plurality of insulation layers may include at least one first insulation layer and at least one second insulation layer. The at least one first insulation layer may include a first insulator including a resin having a Tg value of 200 degrees or more and a filler having a content of 50% to 70%. The at least one second insulation layer may include a second insulator including a glass fiber.

An electronic device according to an example embodiment of the disclosure may comprise: a housing and a printed circuit board disposed in the housing and including an alternately stacked plurality of insulation layers and plurality of conductive layers. The plurality of insulation layers may include at least one first insulation layer having a first thickness and at least one second insulation layer having a second thickness greater than the first thickness. The at least one first insulation layer may include a first insulator including a resin having a Tg value of 200 degrees or more and a filler having a content of 50% to 70%. The at least one second insulation layer may include a second insulator including a glass fiber.

A printed circuit board according to an example embodiment of the disclosure may comprise: an alternately stacked plurality of insulation layers and plurality of conductive layers. The plurality of insulation layers may include at least one first insulation layer having a first thickness and at least one second insulation layer having a second thickness greater than the first thickness. The at least one first insulation layer may include a first insulator including a resin having a Tg value of 200 degrees or more and a filler having a content of 50% to 70%. The at least one second insulation layer may include a second insulator including a glass fiber.

### BRIEF DESCRIPTION OF THE DRAWINGS

The above and other aspects, features and advantages of certain embodiments of the present disclosure will be more apparent from the following detailed description, taken in conjunction with the accompanying drawings, in which:

FIG. 1 is a block diagram illustrating an example electronic device in a network environment according to various embodiments;

FIG. 2 is a front perspective view illustrating an electronic device according to various embodiments;

FIG. 3 is a rear perspective view illustrating the electronic device of FIG. 3 according to various embodiments;

FIG. 4A is a front exploded perspective view illustrating the electronic device of FIG. 2 according to various embodiments;

FIG. 4B is a rear exploded perspective view illustrating the electronic device of FIG. 2 according to various embodiments;

FIG. 5 is a perspective view illustrating a portion of a printed circuit board including a first insulator according to various embodiments;

FIGS. 6 and 7 are cross-sectional views taken along line A-A′ of a portion of the printed circuit board of FIG. 4A according to various embodiments;

FIGS. 8 and 9 are cross-sectional views taken along line A-A′ of a portion of the printed circuit board of FIG. 4A according to various embodiments;

FIGS. 10 and 11 are cross-sectional views taken along line A-A′ of a portion of the printed circuit board of FIG. 4A according to various embodiments; and

FIGS. 12 and 13 are cross-sectional views taken along line A-A′ of a portion of the printed circuit board of FIG. 4A according to various embodiments.

### DETAILED DESCRIPTION

Various example embodiments of the disclosure are now described with reference to the accompanying drawings. However, the disclosure may be implemented in other various forms and is not limited to the example embodiments set forth herein. The same or similar reference denotations may be used to refer to the same or similar elements throughout the disclosure and the drawings. Further, for clarity and brevity, description of well-known functions and configurations in the drawings and relevant descriptions may be omitted.

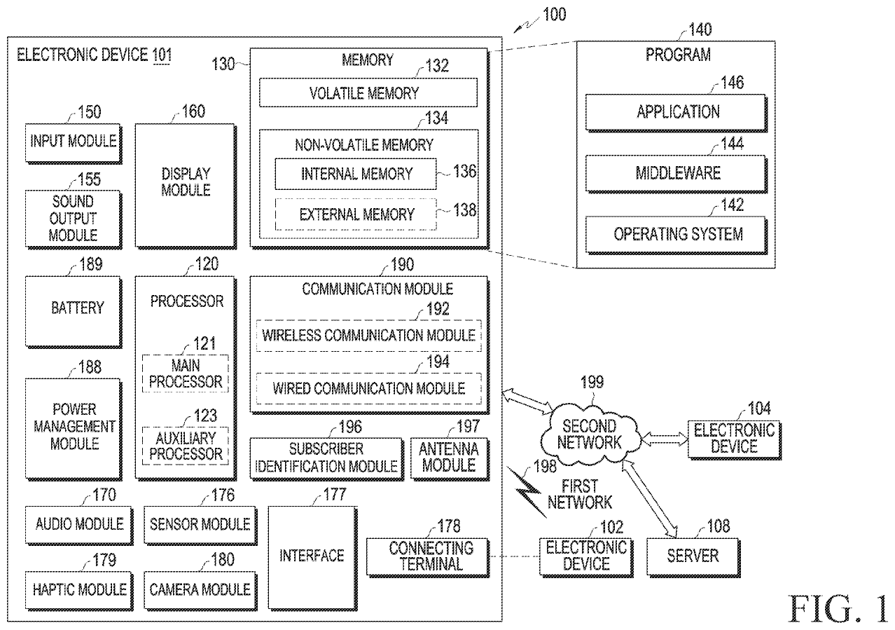

FIG. 1 is a block diagram illustrating an example electronic device in a network environment according to various embodiments.

Referring to FIG. 1, the electronic device 101 in the network environment 100 may communicate with an electronic device 102 via a first network 198 (e.g., a short-range wireless communication network), or an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In an embodiment, at least one (e.g., the connecting terminal 178) of the components may be omitted from the electronic device 101, or one or more other components may be added in the electronic device 101. In an embodiment, some (e.g., the sensor module 176, the camera module 180, or the antenna module 197) of the components may be integrated into a single component (e.g., the display module 160).

The processor 120 may include various processing circuitry and/or multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited/disclosed functions, e.g., in a distributed manner. At least one processor may execute program instructions to achieve or perform various functions. The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be configured to use lower power than the main processor 121 or to be specified for a designated function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. The artificial intelligence model may be generated via machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by other component (e.g., the processor 120) of the electronic device 101, from the outside (e.g., a user) of the electronic device 101. The input module 150 may include, for example, a microphone, a mouse, a keyboard, keys (e.g., buttons), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display 160 may include, for example, a display, a hologram device, or a projector and control circuitry to control a corresponding one of the display, hologram device, and projector. According to an embodiment, the display 160 may include a touch sensor configured to detect a touch, or a pressure sensor configured to measure the intensity of a force generated by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or motion) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device 104 via a first network 198 (e.g., a short-range communication network, such as Bluetooth™, wireless-fidelity (Wi-Fi) direct, or infrared data association (IrDA)) or a second network 199 (e.g., a long-range communication network, such as a legacy cellular network, a 5G network, a next-generation communication network, the Internet, or a computer network (e.g., local area network (LAN) or wide area network (WAN)). These various types of communication modules may be implemented as a single component (e.g., a single chip), or may be implemented as multi components (e.g., multi chips) separate from each other. The wireless communication module 192 may identify or authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mm Wave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device). According to an embodiment, the antenna module 197 may include one antenna including a radiator formed of a conductor or conductive pattern formed on a substrate (e.g., a printed circuit board (PCB)). According to an embodiment, the antenna module 197 may include a plurality of antennas (e.g., an antenna array). In this case, at least one antenna appropriate for a communication scheme used in a communication network, such as the first network 198 or the second network 199, may be selected from the plurality of antennas by, e.g., the communication module 190. The signal or the power may then be transmitted or received between the communication module 190 and the external electronic device via the selected at least one antenna. According to an embodiment, other parts (e.g., radio frequency integrated circuit (RFIC)) than the radiator may be further formed as part of the antenna module 197.

According to an embodiment, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, instructions or data may be transmitted or received between the electronic device 101 and the external electronic device 104 via the server 108 coupled with the second network 199. The external electronic devices 102 or 104 each may be a device of the same or a different type from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In an embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

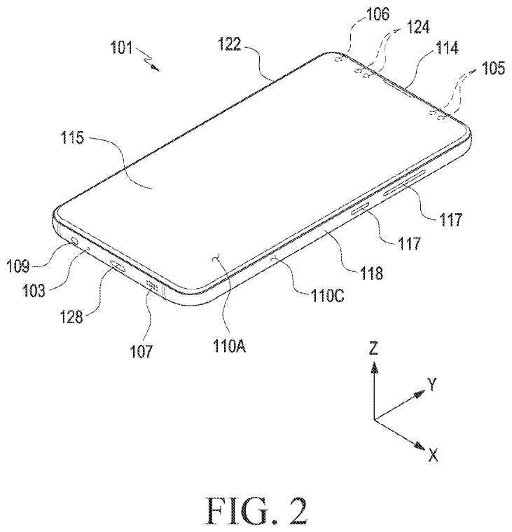

FIG. 2 is a front perspective view illustrating an example electronic device 101 according to various embodiments.

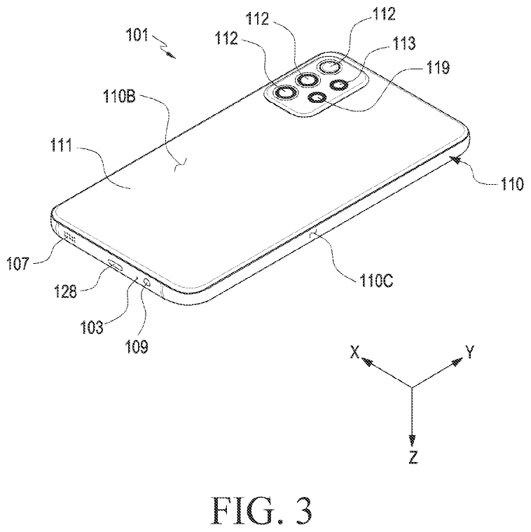

FIG. 3 is a rear perspective view illustrating the electronic device 101 of FIG. 2 according to various embodiments.

Referring to FIGS. 2 and 3, according to an embodiment, an electronic device 101 (e.g., the electronic device 101 of FIG. 1) may include a housing 110 including a first surface (or front surface) 110A, a second surface (or rear surface) 110B, and a side surface 110C surrounding a space between the first surface 110A and the second surface 110B. According to an embodiment (not shown), the housing 110 may denote a structure forming the first surface 110A of FIG. 2, the second surface 110B of FIG. 3, and some of the side surfaces 110C.

According to an embodiment, at least part of the first surface 110A may have a substantially transparent front plate 122 (e.g., a glass plate or polymer plate including various coat layers). The second surface 110B may be formed of a substantially opaque rear plate 111. The rear plate 111 may be formed of, e.g., laminated or colored glass, ceramic, polymer, metal (e.g., aluminum, stainless steel (STS), or magnesium), or a combination of at least two thereof. The side surface 110C may be formed by a side structure (or a “side bezel structure”) 118 that couples to the front plate 122 and the rear plate 111 and includes a metal and/or polymer. In an embodiment, the rear plate 111 and the side structure 118 may be integrally formed together and include the same material (e.g., a metal, such as aluminum).

According to an embodiment, the front plate 122 may include area(s) that bend from at least a portion of an edge toward the rear plate 111 and seamlessly extend. For example, only one of the areas of the front plate 122 (or the rear plate 111), which bend to the rear plate 111 (or front plate 122) and extend may be included in one edge of the first surface 110A. According to an embodiment, the front plate 122 or rear plate 111 may be substantially flat and, in this case, may not include an area bending and extending. When an area bending and extending is included in the front plate 122 or rear plate 111, the thickness of the electronic device 101 at the portion including the area bending and extending may be smaller than the thickness of the rest.

According to an embodiment, the electronic device 101 may include at least one of a display 115, an audio module (e.g., the microphone hole 103, the external speaker hole 107, and the phone receiver hole 114), a sensor module (e.g., the first sensor module 124, the second sensor module (not illustrated), or the third sensor module 119), a camera module (e.g., the first camera device 105, the second camera device 112, or the flash 113), a key input device 117, a light emitting device 106, and a connector hole (e.g., the first connector hole 128 or the second connector hole 109). In an embodiment, the electronic device 101 may exclude at least one (e.g., the key input device 117 or the light emitting device 106) of the components or may add other components.

The display 115 may output a screen or be visible through a significant portion of the first surface 110A (e.g., the front plate 122), for example. In an embodiment, at least a portion of the display 115 may be visible through the front plate 122 forming the first surface 110A, or through a portion of the side surface 110C. In an embodiment, the edge of the display 115 may be formed to be substantially the same in shape as an adjacent outer edge of the front plate 122. In an embodiment (not shown), the interval between the outer edge of the display 115 and the outer edge of the front plate 122 may remain substantially even to give a larger area of visual exposure of the display 115.

According to an embodiment, a recess or an opening may be formed in a portion of the screen display area of the display 115, and there may be included at least one of an audio module (e.g., the phone receiver hole 114), a sensor module (e.g., the first sensor module 124), a camera module (e.g., the first camera device 105), and a light emitting device 106 that are aligned with the recess or the opening. In an embodiment (not shown), at least one of the audio module (e.g., the phone receiver hole 114), sensor module (e.g., the first sensor module 124), camera module (e.g., the first camera device 105), fingerprint sensor (not shown), and light emitting device 106 may be included on the rear surface of the screen display area of the display 115. In an embodiment (not shown), the display 115 may be disposed to be coupled with, or adjacent, a touch detecting circuit, a pressure sensor capable of measuring the strength (pressure) of touches, and/or a digitizer for detecting a magnetic field-type stylus pen.

According to an embodiment, the audio modules 103, 107, and 114 may include a microphone hole 103 and speaker holes (e.g., the external speaker hole 107 and the phone receiver hole 114). A microphone for acquiring external sounds may be disposed in the microphone hole 103. In an embodiment, a plurality of microphones may be disposed to detect the direction of the sound. The speaker holes may include an external speaker hole 107 and a phone receiver hole 114. According to an embodiment, the speaker holes (e.g., the external speaker hole 107 and the phone receiver hole 114) and the microphone hole 103 may be implemented as a single hole, or speakers may be included without the speaker holes (e.g., the external speaker hole 107 and the phone receiver hole 114) (e.g., piezo speakers).

According to an embodiment, the sensor module may generate an electrical signal or data value corresponding to an internal operating state or external environmental state of the electronic device 101. The sensor modules may include a first sensor module 124 (e.g., a proximity sensor) and/or a second sensor module (not shown) (e.g., a fingerprint sensor) disposed on the first surface 110A of the housing 110 and/or a third sensor module 119 disposed on the second surface 110B of the housing 110. The second sensor module (not shown) (e.g., a fingerprint sensor) may be disposed on the second surface 110B or side surface 110C as well as the first surface 110A (e.g., the display 115) of the housing 110. The electronic device 101 may further include, e.g., at least one of a gesture sensor, a gyro sensor, an atmospheric pressure sensor, a magnetic sensor, an acceleration sensor, a grip sensor, a color sensor, an infrared (IR) sensor, a biometric sensor, a temperature sensor, a humidity sensor, or an illuminance sensor 124.

According to an embodiment, the camera modules may include a first camera device 105 disposed on the first surface 110A of the electronic device 101, and a second camera device 112 and/or a flash 113 disposed on the second surface 110B. The camera devices (e.g., the first camera device 105 and the second camera device 112) may include one or more lenses, an image sensor, and/or an image signal processor. The flash 113 may include, e.g., a light emitting diode (LED) or a xenon lamp. In an embodiment, one or more lenses (an infrared (IR) camera, a wide-angle lens, and a telephoto lens) and image sensors may be disposed on one surface of the electronic device 101. In an embodiment, flash 113 may emit infrared light. The infrared light emitted by the flash 113 and reflected by the subject may be received through the third sensor module 119. The electronic device 101 or the processor (e.g., the processor 120 of FIG. 1) of the electronic device 101 may detect depth information about the subject based on the time point when the infrared light is received from the third sensor module 119.

According to an embodiment, the key input device 117 may be disposed on the side surface 110C of the housing 110. In an embodiment, the electronic device 101 may exclude all or some of the above-mentioned key input devices 117 and the excluded key input devices 117 may be implemented in other forms, e.g., as soft keys, on the display 115. In an embodiment, the key input device may include the sensor module disposed on the second surface 110B of the housing 110.

According to an embodiment, the light emitting device 106 may be disposed on the first surface 110A of the housing 110, for example. The light emitting device 106 may provide, e.g., information about the state of the electronic device 101 in the form of light. In an embodiment, the light emitting device 106 may provide a light source that interacts with, e.g., the camera module (e.g., the first camera device 105). The light emitting device 106 may include, e.g., a light emitting diode (LED), an infrared (IR) LED, or a xenon lamp.

According to an embodiment, the connector holes (e.g., the first connector hole 128 or the second connector hole 109) may include, e.g., a first connector hole 128 for receiving a connector (e.g., a USB connector) for transmitting/receiving power and/or data to/from an external electronic device (e.g., the electronic device 102 of FIG. 1) and/or a second connector hole 109 (e.g., an earphone jack) for receiving a connector for transmitting/receiving audio signals to/from the external electronic device.

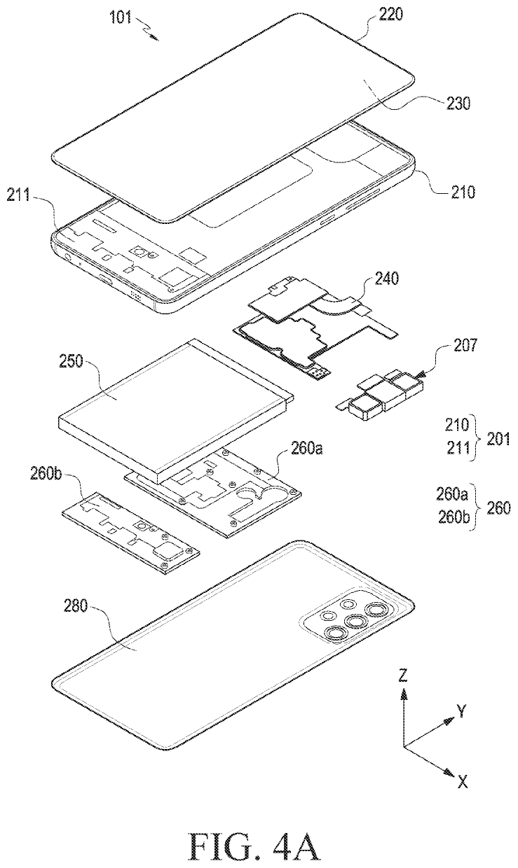

FIG. 4A is a front exploded perspective view illustrating the electronic device 101 of FIG. 2 according to various embodiments.

FIG. 4B is a rear exploded perspective view illustrating the electronic device 101 of FIG. 2 according to various embodiments.

Referring to FIGS. 4A and 4B, an electronic device 101 (e.g., the electronic device 101 of FIG. 1, 2, or 3) may include a side structure 210 (e.g., the side structure 118 of FIG. 2), a first supporting member 211 (e.g., a bracket), a front plate 220 (e.g., the front plate 122 of FIG. 2), a display 230 (e.g., the display 115 of FIGS. 2 and 3), a printed circuit board (or a board assembly) 240, a battery 250, a second supporting member 260 (e.g., a rear case), an antenna, a camera assembly 207, and a rear plate 280 (e.g., the rear plate 111 of FIG. 3).

According to an embodiment, the electronic device 101 may exclude at least one (e.g., the first supporting member 211 or the second supporting member 260) of the components or may add other components. At least one of the components of the electronic device 101 may be the same or similar to at least one of the components of the electronic device 101 of FIG. 2 or 3 and no duplicate description is made below.

According to an embodiment, the first supporting member 211 may be disposed inside the electronic device 101 to be connected with the side structure 210 or integrated with the side structure 210. The first supporting member 211 may be formed of, e.g., a metal and/or non-metallic material (e.g., polymer). When at least partially formed of a metallic material, a portion of the side structure 210 or the first supporting member 211 may function as an antenna. The display 230 may be joined onto one surface of the first supporting member 211, and the printed circuit board 240 may be joined onto the opposite surface of the first supporting member 311. A processor (e.g., the processor 120 of FIG. 1), a memory (e.g., the memory 130 of FIG. 1), and/or an interface (e.g., the interface 177 of FIG. 1) may be mounted on the printed circuit board 240. The processor may include one or more of, e.g., a central processing unit, an application processor, a graphic processing device, an image signal processing, a sensor hub processor, or a communication processor.

According to an embodiment, the first supporting member 211 and the side structure 210 may be collectively referred to as a front case or a housing 201. According to an embodiment, the housing 201 may be generally understood as a structure for receiving, protecting, or disposing the printed circuit board 240 or the battery 250. In an embodiment, the housing 201 may be understood as including a structure that the user may visually or tactfully recognize from the exterior of the electronic device 101, e.g., the side structure 210, the front plate 220, and/or the rear plate 280. In an embodiment, the ‘front or rear surface of the housing 201’ may refer, for example, to the first surface 110A of FIG. 2 or the second surface 110B of FIG. 3. In an embodiment, the first supporting member 211 may be disposed between the front plate 220 (e.g., the first surface 110A of FIG. 2) and the rear plate 280 (e.g., the second surface 110B of FIG. 3) and may function as a structure for placing an electrical/electronic component, such as the printed circuit board 240 or the camera assembly 207.

According to an embodiment, the display 230 may include a display panel 231 and a flexible printed circuit board 233 extending from the display panel 231. It may be understood that the flexible printed circuit board 233 is, e.g., electrically connected to the display panel 231 while at least partially disposed on the rear surface of the display panel 231. In an embodiment, reference number ‘231’ may be understood as a protective sheet disposed on the rear surface of the display panel. For example, the protective sheet may be understood as a portion of the display panel 231 unless otherwise designated in the detailed description below. In an embodiment, the protective sheet may function as a cushioning structure that absorbs external force (e.g., a low-density elastic material, such as a sponge) or an electromagnetic shielding structure (e.g., a copper sheet (CU sheet)). According to an embodiment, the display 230 may be disposed on the inner surface of the front plate 220 and, by including a light emitting layer, output a screen through at least a portion of the front plate 220 or the first surface 110A of FIG. 2. As mentioned above, the display 230 may output substantially the entire area of the front plate 220 or the first surface 110A of FIG. 2.

According to an embodiment, the memory may include, e.g., a volatile or non-volatile memory.

According to an embodiment, the interface may include, e.g., a high definition multimedia interface (HDMI), a universal serial bus (USB) interface, a secure digital (SD) card interface, and/or an audio interface. The interface may electrically or physically connect, e.g., the electronic device 101 with an external electronic device and may include a USB connector, an SD card/multimedia card (MMC) connector, or an audio connector.

According to an embodiment, the second supporting member 260 may include, e.g., an upper supporting member 260a and a lower supporting member 260b. In an embodiment, the upper supporting member 260a, together with a portion of the first supporting member 211, may be disposed to surround the printed circuit board 240. A circuit device (e.g., a processor, a communication module, or a memory) implemented in the form of an integrated circuit chip or various electrical/electronic components may be disposed on the printed circuit board 240. According to an embodiment, the printed circuit board 240 may receive an electromagnetic shielding environment from the upper supporting member 260a. In an embodiment, the lower supporting member 260b may be utilized as a structure in which electrical/electronic components, such as a speaker module and an interface (e.g., a USB connector, an SD card/MMC connector, or an audio connector) may be disposed. In an embodiment, electrical/electronic components, such as a speaker module and an interface (e.g., a USB connector, an SD card/MMC connector, or an audio connector) may be disposed on an additional printed circuit board (not shown). For example, the lower supporting member 260b, together with the other part of the first supporting member 211, may be disposed to surround the additional printed circuit board. A speaker module or interface disposed on an additional printed circuit board (not shown) or lower supporting member 260b may be disposed corresponding to the connector hole (e.g., the first connector hole 128 or the second connector hole 109) or the audio module (e.g., the microphone hole 103 or the speaker hole (e.g., the external speaker hole 107 or the phone receiver hole 114)) of FIG. 2.

According to an embodiment, the battery 250 may be a device for supplying power to at least one component of the electronic device 101. The battery 189 may include, e.g., a primary cell which is not rechargeable, a secondary cell which is rechargeable, or a fuel cell. At least a portion of the battery 250 may be disposed on substantially the same plane as the printed circuit board 240. The battery 250 may be integrally or detachably disposed inside the electronic device 101.

Although not shown, the antenna may include a conductor pattern implemented on the surface of the second supporting member 260 through, e.g., laser direct structuring. In an embodiment, the antenna may include a printed circuit pattern formed on the surface of the thin film. The thin film-type antenna may be disposed between the rear plate 280 and the battery 250. The antenna may include, e.g., a near-field communication (NFC) antenna, a wireless charging antenna, and/or a magnetic secure transmission (MST) antenna. The antenna may perform short-range communication with, e.g., an external device or may wirelessly transmit or receive power necessary for charging. In an embodiment of the present disclosure, another antenna structure may be formed by a portion or combination of the side structure 210 and/or the first supporting member 211.

According to an embodiment, the camera assembly 207 may include at least one camera module. Inside the electronic device 101, the camera assembly 207 may receive at least a portion of the light incident through the optical hole or the camera windows 212, 213, and 219. In an embodiment, the camera assembly 207 may be disposed on the first supporting member 211 in a position adjacent to the printed circuit board 240. In an embodiment, the camera module(s) of the camera assembly 207 may be generally aligned with either one of the camera windows 212, 213, and 219 and be a least partially surrounded by the second supporting member 260 (e.g., the upper supporting member 260a).

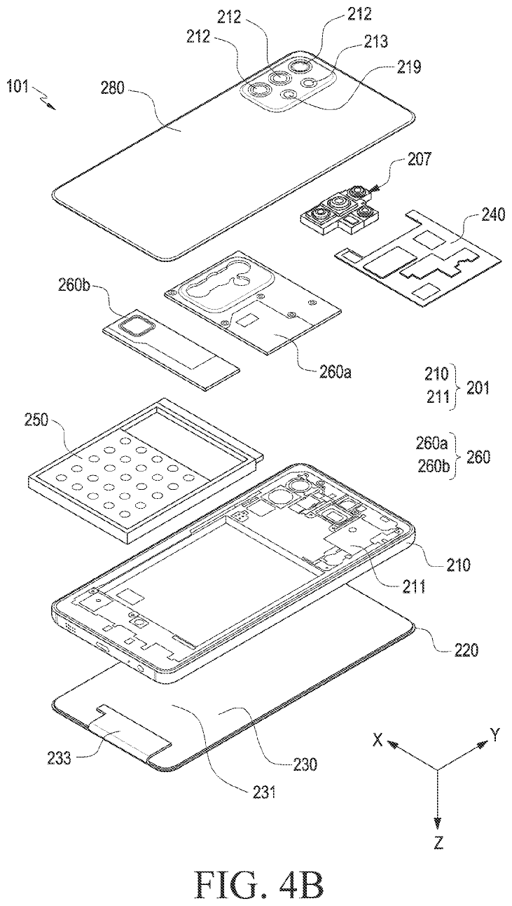

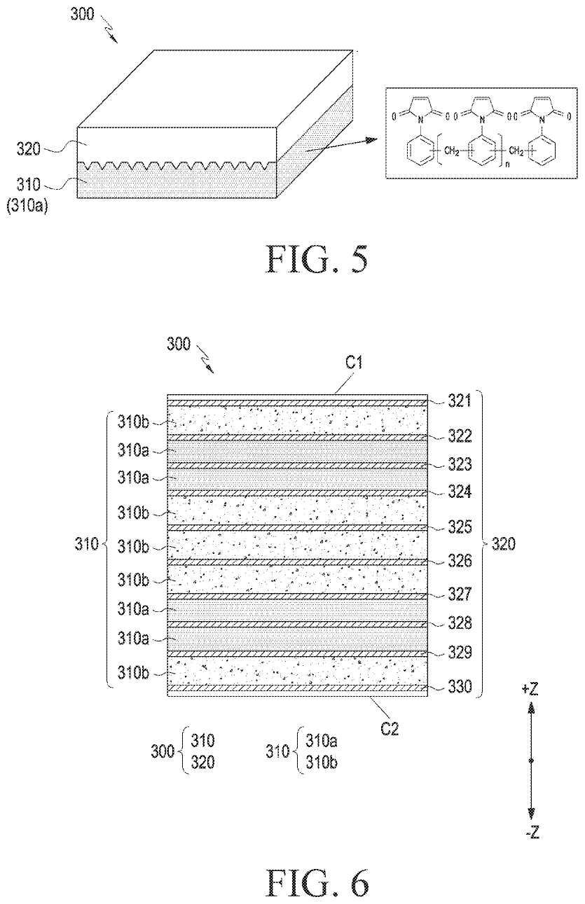

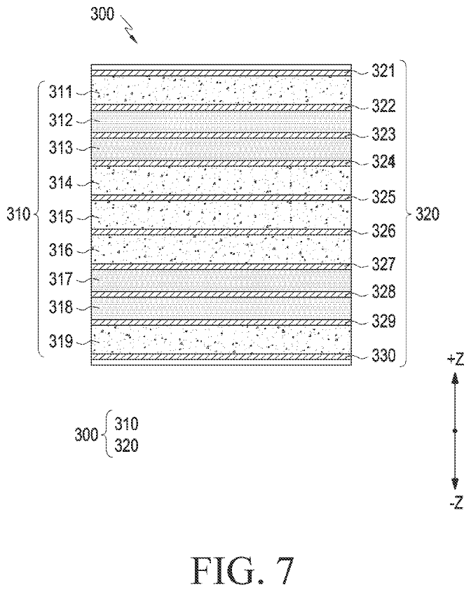

FIG. 5 is a perspective view illustrating a portion of a printed circuit board including a first insulator according to various embodiments. FIGS. 6 and 7 are cross-sectional views taken along line A-A′ of a portion of the printed circuit board of FIG. 4A according to various embodiments.

Referring to FIGS. 5, 6 and 7 (which may be referred to as FIGS. 5 to 7), the electronic device 101 may include a housing (e.g., the housing 201 of FIG. 4) and a printed circuit board 300. The configuration of the printed circuit board 300 of FIGS. 5 to 7 may be identical in whole or part to the configuration of the printed circuit board 240 of FIGS. 2 to 4. The structure of FIGS. 5 to 7 may be selectively combinable with the structures of FIGS. 2 to 4.

According to an embodiment, the printed circuit board 300 may be disposed in the housing (e.g., the housing 201 of FIG. 4). According to an embodiment, the printed circuit board 300 may be a printed circuit board for high-density interconnect (HDI). For example, the size and/or area of the printed circuit board 300 may be about 400 mm² or more. For example, the size and/or area of the printed circuit board 300 may be about 20 mm long horizontally and about 20 mm long vertically.

According to an embodiment, the printed circuit board 300 may be a multi-layer printed circuit board comprising a plurality of layers. According to an embodiment, the printed circuit board 300 may include an insulation layer 310, a conductive layer 320, and at least one via hole (not shown) configured to penetrate the insulation layer 310. According to an embodiment, the printed circuit board 300 may have a structure in which a plurality of insulation layers 310 and a plurality of conductive layers 320 are alternately stacked.

According to an embodiment, the plurality of conductive layers 320 may be formed of a conductor (e.g., copper foil), and have a circuit pattern formed on at least a portion thereof. Each of the conductive layers (e.g., 321, 322, 323, 324, 325, 326, 327, 328, 329, and 330 of FIG. 7) of the plurality of conductive layers 320 may be disposed between the insulation layers (e.g., 311, 312, 313, 314, 315, 316, 317, 318, and 319 of FIG. 7) of the plurality of insulation layers 310. For example, the conductive layer 320 may be formed by casting, laminating, or sputtering.

According to an embodiment, each insulation layer (e.g., 311, 312, 313, 314, 315, 316, 317, 318, and 319 of FIG. 7) of the plurality of insulation layers 310 may be disposed between conductive layers (e.g., 321, 322, 323, 324, 325, 326, 327, 328, 329, and 330 of FIG. 7) of the plurality of conductive layers 320.

According to an embodiment, the plurality of insulation layers 310 may include at least one first insulator 310a and at least one second insulator 310b having different components from the first insulator 310a. According to an embodiment, the second insulator 310b may include glass fiber. For example, the second insulator 310b may use a prepreg. For example, the second insulator 310b may be comprise a resin, a filler, and glass fiber.

According to an embodiment, the resin of the second insulator 310b may have a lower Tg value than the resin of the first insulator 310a. For example, the Tg value of the resin of the second insulator 310b may be about 150 degrees or less. The Tg value of the resin may refer, for example, to the glass transition temperature. Tg may be a characteristic of a material related to the behavior of the molecular structure of epoxy cured at a high temperature. For example, it may refer, for example, to the properties of the polymer being lost at a temperature above Tg.

According to an embodiment, the second insulator 310b may include a film-type adhesive and may be manufactured for a flexible printed circuit board. The second insulator 310b may have a characteristic of suppressing the flow of resin to prevent and/or reduce resin invasion of the flex portion of the flexible printed circuit board. In this case, the Tg value of the second insulator 310b may be about 120 degrees or less. The coefficient of thermal expansion (CTE) of the second insulator 310b may be relatively high.

According to an embodiment, the second insulator 310b may include a film-type adhesive, and may be used for a fine pattern printed circuit board according to a semi-additive process (SAP) circuit method. In this case, the Tg value of the second insulator 310b may be about 150 degrees or less. The permittivity Dk of the second insulator 310b may be about 3.5 or more.

According to an embodiment, the second insulator 310b may include only resin. the second insulator 310b may include a resin coated copper foil (RCC) comprising resin used to facilitate via processing when laser vias are not used. For example, the Tg value of the second insulator 310b may be about 120 degrees or less.

According to an embodiment, the thickness of the insulation layer (e.g., 311, 314, 315, 316, and 319 of FIG. 7) formed of the second insulator 310b may be larger than the thickness of the insulation layer (e.g., 312, 313, 317, and 318 of FIG. 7) formed of the first insulator 310a. For example, the insulation layer (e.g., 311, 314, 315, 316, and 319 of FIG. 7) formed of the second insulator 310b may have a thickness of about 25 μm or more.

According to an embodiment, the first insulator 310a may include a resin and a filler. According to an embodiment, the filler may include a silica-based material, for example, silicon dioxide (SiO₂). However, the materials included in the filler may not necessarily be limited thereto. According to an embodiment, the first insulator 310a may include a resin coated copper foil (RCC) including a resin and a filler.

According to an embodiment, the first insulator 310a may not include glass fiber. Unlike the second insulator 310b (e.g., prepreg), since the glass fiber is not included in the first insulator 310a, the exposed portions of copper (cu) and epoxy may be filled without resin voids when manufacturing the ultra-thin insulation layers.

According to an embodiment, referring to FIG. 5, the resin content of the first insulator 310a may be higher than the resin content of the second insulator 310b having the same thickness. For example, the resin of the second insulator 310b may have a higher Tg value than the resin of the first insulator 310a. For example, the Tg value of the first insulator 310a may be about 200 degrees or more. For example, the Tg value of the first insulator 310a may be 280 degrees or more. The formula shown in FIG. 5 may be the formula (CH2═C(R′)—COOR) of resin.

According to an embodiment, the filler content of the first insulator 310a may be higher than the filler content of the second insulator 310b. For example, the first insulator 310a may include a filler having a content of about 50% or more and about 70% or less. For example, the first insulator 310a may include a filler having a content of about 60% or more and about 70% or less. The first insulator 310a may be allowed to have a low dielectric constant value by appropriately allocating the contents of the resin and the filler.

According to an embodiment, the permittivity Dk of the first insulator 310a may be lower than that of the second insulator 310b. For example, the permittivity Dk of the first insulator 310a may be about 3.0 or less. For example, the permittivity Dk of the first insulator 310a may be about 2.9 or less.

According to an embodiment, the dielectric loss Df of the first insulator 310a may be lower than the dielectric loss Df of the second insulator 310b. For example, the dielectric loss Df of the first insulator 310a may be about 0.005 or less. For example, the dielectric loss Df of the first insulator 310a may be about 0.004 or less. Since the permittivity Dk and the dielectric loss Df of the first insulator 310a are low, electrical interference may be reduced, thereby reducing the thickness of the printed circuit board.

According to an embodiment, the thickness of the insulation layers (e.g., 312, 313, 317, and 318 of FIG. 7) formed of the first insulator 310a may be smaller than the thickness of the insulation layers (e.g., 311, 314, 315, 316, and 319 of FIG. 7) formed of the second insulator 310b. For example, compared to the thickness of the insulating layer (e.g., 311, 314, 315, 316, 319 in FIG. 7) made of the second insulator 310b of about 25 μm, the insulation layer (e.g., 312, 313, 317, and 318 of FIG. 7) formed of the first insulator 310a may have a thickness of about 20 μm or less.

According to an embodiment, the multi-layer printed circuit board 300 may include a plurality of layers. Each layer of the multi-layer printed circuit board 300 may include an insulation layer 310 and a conductive layer 320 stacked on the insulation layer 310.

For example, referring to FIGS. 6 and 7, the plurality of insulation layers 310 of the multi-layer printed circuit board 300 may include a first insulation layer 311, a second insulation layer 312, a third insulation layer 313, a fourth insulation layer 314, a fifth insulation layer 315, a sixth insulation layer 316, a seventh insulation layer 317, an eighth insulation layer 318, and a ninth insulation layer 319. For example, the plurality of conductive layers 320 of the multi-layer printed circuit board 300 may include a first conductive layer 321, a second conductive layer 322, a third conductive layer 323, a fourth conductive layer 324, a fifth conductive layer 325, a sixth conductive layer 326, a seventh conductive layer 327, an eighth conductive layer 328, a ninth conductive layer 329, and a tenth conductive layer 330. For example, the multi-layer printed circuit board 300 may be a printed circuit board 300 comprising about 10 layers sequentially stacked and disposed including the first conductive layer 321, the first insulation layer 311, the second conductive layer 322, the second insulation layer 312, the third conductive layer 323, the third insulation layer 313, the fourth conductive layer 324, the fourth insulation layer 314, the fifth conductive layer 325, the fifth insulation layer 315, the sixth conductive layer 326, the sixth insulation layer 316, the seventh conductive layer 327, the seventh insulation layer 317, the eighth conductive layer 328, the eighth insulation layer 318, the ninth conductive layer 329, the ninth insulation layer 319, and the tenth conductive layer 330.

According to an embodiment, the plurality of insulation layers 310 of the multi-layer printed circuit board 300 may be any one of the first insulator 310a or the second insulator 310b. According to an embodiment, the type (e.g., the first insulator 310a or the second insulator 310b), the number, and the arrangement of the insulators may be selectively designated according to the thickness required for the printed circuit board 300. For example, when a thin insulator is required, the first insulator 310a may be disposed. For example, when the insulation layers of the printed circuit board 300 are configured only with the first insulator 310a, warpage may occur or may deteriorate in terms of rigidity, and thus the second insulator 310b including glass fiber may be appropriately disposed. For example, the second insulator 310b may be disposed in at least a portion of a central portion or an edge portion (an upper portion or a lower portion) with respect to the stacking direction (e.g., the Z-axis direction of FIG. 6) to secure rigidity of the printed circuit board 300. For example, the rigidity of the printed circuit board 300 may be about 430,000 (N/m) or more.

According to an embodiment, among the plurality of insulation layers 310 of the multi-layer printed circuit board 300, the insulation layer disposed at the central portion with respect to the stacking direction (e.g., the Z-axis direction of FIG. 6) may be formed of the second insulator 310b. For example, the fifth insulation layer 315 may be formed of the second insulator 310b. According to an embodiment, the configuration of the plurality of insulation layers 310 of the multi-layer printed circuit board 300 may be symmetrically disposed with respect to the insulation layer (e.g., the fifth insulation layer 315 of FIG. 5) disposed at the central portion thereof.

According to an embodiment, among the plurality of insulation layers 310 of the multi-layer printed circuit board 300, the insulation layer disposed at the edge portion with respect to the stacking direction (e.g., the Z-axis direction of FIG. 6) may be formed of the second insulator 310b. For example, the first insulation layer 311 and the ninth insulation layer 319 may be formed of the second insulator 310b.

For example, referring to FIG. 7, the first insulation layer 311, the fourth insulation layer 314, the fifth insulation layer 315, the sixth insulation layer 316, and the ninth insulation layer 319 may be formed of the second insulator 310b. For example, referring to FIG. 7, the second insulation layer 312, the third insulation layer 313, the seventh insulation layer 317, and the eighth insulation layer 318 may be formed of the first insulator 310a.

According to one embodiment, referring to FIG. 7, protective layers c1 and c2 may be additionally provided on the surface of the multi-layer printed circuit board 300. The protective layers c1 and c2 may protect the surface of the multi-layer printed circuit board 300 from physical, electrical and/or chemical shock. The protective layers (c1, c2) may also serve to identify portions which require soldering. For example, the protective layers c1 and c2 may be referred to as photo solder resist (PSR). The protective layers c1 and c2 may be omitted depending on the embodiment. In the embodiments described below, description of the protective layers c1 and c2 will be omitted for convenience.

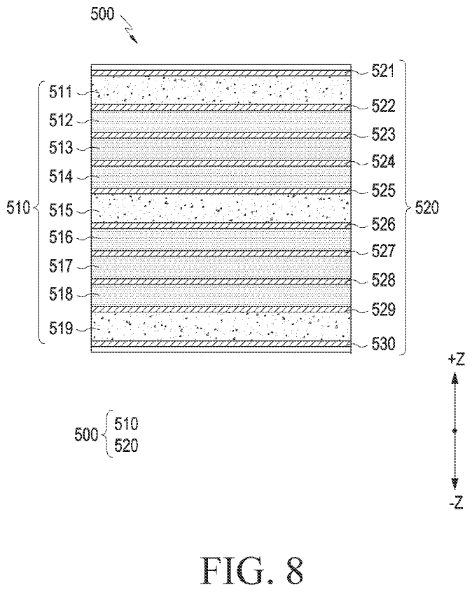

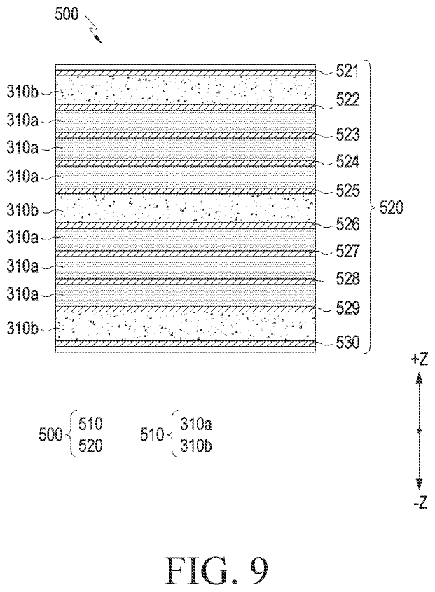

FIGS. 8 and 9 are cross-sectional views taken along line A-A′ of a portion of the printed circuit board of FIG. 4A according to various embodiments.

Referring to FIGS. 8 and 9, the electronic device 101 may include a housing (e.g., the housing 201 of FIG. 4) and a printed circuit board 500. The configuration of the printed circuit board 500 of FIGS. 8 and 9 may be identical in whole or part to the configuration of the printed circuit board 300 of FIGS. 5 to 7. The structure of FIGS. 8 and 9 may be selectively combinable with the structures of FIGS. 5 to 7.

According to an embodiment, the multi-layer printed circuit board 500 may include a plurality of layers. Each layer of the multi-layer printed circuit board 500 may include an insulation layer 510 and a conductive layer 520 stacked on the insulation layer 510.

For example, referring to FIGS. 8 and 9, the plurality of insulation layers 510 of the multi-layer printed circuit board 500 may include a first insulation layer 511, a second insulation layer 512, a third insulation layer 513, a fourth insulation layer 514, a fifth insulation layer 515, a sixth insulation layer 516, a seventh insulation layer 517, an eighth insulation layer 518, and a ninth insulation layer 519. For example, the plurality of conductive layers 520 of the multi-layer printed circuit board 500 may include a first conductive layer 521, a second conductive layer 522, a third conductive layer 523, a fourth conductive layer 524, a fifth conductive layer 525, a sixth conductive layer 526, a seventh conductive layer 527, an eighth conductive layer 528, a ninth conductive layer 529, and a tenth conductive layer 530. For example, the multi-layer printed circuit board 500 may be a printed circuit board 500 comprising 10 layers sequentially stacked and disposed including the first conductive layer 521, the first insulation layer 511, the second conductive layer 522, the second insulation layer 512, the third conductive layer 523, the third insulation layer 513, the fourth conductive layer 524, the fourth insulation layer 514, the fifth conductive layer 525, the fifth insulation layer 515, the sixth conductive layer 526, the sixth insulation layer 516, the seventh conductive layer 527, the seventh insulation layer 517, the eighth conductive layer 528, the eighth insulation layer 518, the ninth conductive layer 529, the ninth insulation layer 519, and the tenth conductive layer 530.

According to an embodiment, the plurality of insulation layers 510 of the multi-layer printed circuit board 500 may be any one of the first insulator 310a or the second insulator 310b. According to an embodiment, the type (e.g., the first insulator 310a or the second insulator 310b), the number, and the arrangement of the insulators may be selectively designated according to the thickness required for the printed circuit board. For example, when a thin insulator is required, the first insulator 310a may be disposed. For example, when the insulation layers of the printed circuit board are configured only with the first insulator 310a, warpage may occur or may deteriorate in terms of rigidity, and thus the second insulator 310b including glass fiber may be appropriately disposed. For example, the second insulator 310b may be disposed in at least a portion of a central portion or an edge portion (an upper portion or a lower portion) with respect to the stacking direction (e.g., the Z-axis direction of FIG. 9) to secure rigidity of the printed circuit board 500. For example, the rigidity of the printed circuit board 500 may be about 450,000 (N/m) or more.

According to an embodiment, among the plurality of insulation layers 510 of the multi-layer printed circuit board 500, the insulation layer disposed at the central portion with respect to the stacking direction (e.g., the Z-axis direction of FIG. 9) may be formed of the second insulator 310b. For example, the fifth insulation layer 515 may be formed of the second insulator 310b. According to an embodiment, the configuration of the plurality of insulation layers 510 of the multi-layer printed circuit board 500 may be symmetrically disposed with respect to the insulation layer (e.g., the fifth insulation layer 515 of FIG. 8) disposed at the central portion thereof.

According to an embodiment, among the plurality of insulation layers 510 of the multi-layer printed circuit board 500, the insulation layer disposed at the edge portion with respect to the stacking direction (e.g., the Z-axis direction of FIG. 9) may be formed of the second insulator 310b. For example, the first insulation layer 511 and the ninth insulation layer 519 may be formed of the second insulator 310b.

For example, referring to FIG. 9, the first insulation layer 511, the fifth insulation layer 515, and the ninth insulation layer 519 may be formed of the second insulator 310b. For example, referring to FIG. 9, the second insulation layer 512, the third insulation layer 513, the fourth insulation layer 514, the sixth insulation layer 516, the seventh insulation layer 517, and the eighth insulation layer 518 may be formed of the first insulator 310a.

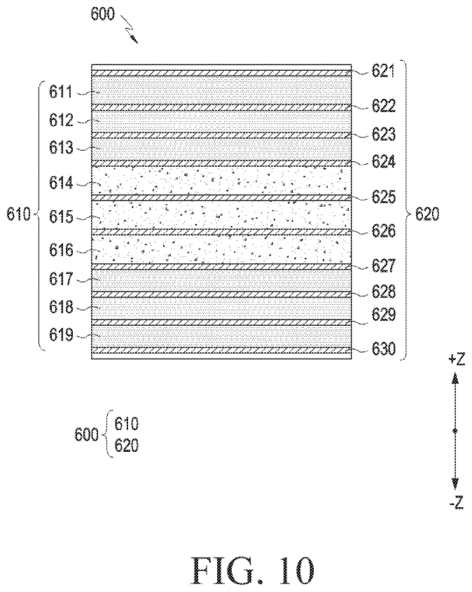

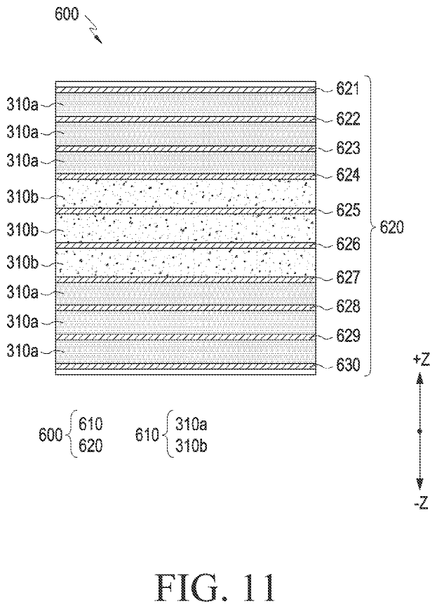

FIGS. 10 and 11 are cross-sectional views taken along line A-A′ of a portion of the printed circuit board of FIG. 4A according to various embodiments.

Referring to FIGS. 10 and 11, the electronic device 101 may include a housing (e.g., the housing 201 of FIG. 4) and a printed circuit board 600. The configuration of the printed circuit board 600 of FIGS. 10 and 11 may be identical in whole or part to the configuration of the printed circuit board 300 or 500 of FIGS. 6, 7, 8 and 9 (which may be referred to as FIGS. 6 to 9). The structure of FIGS. 10 and 11 may be selectively combinable with the structures of FIGS. 6 to 9.

According to an embodiment, the multi-layer printed circuit board 600 may include a plurality of layers. Each layer of the multi-layer printed circuit board 600 may include an insulation layer 610 and a conductive layer 620 stacked on the insulation layer 610.

For example, referring to FIGS. 10 and 11, the plurality of insulation layers 610 of the multi-layer printed circuit board 600 may include a first insulation layer 611, a second insulation layer 612, a third insulation layer 613, a fourth insulation layer 614, a fifth insulation layer 615, a sixth insulation layer 616, a seventh insulation layer 617, an eighth insulation layer 618, and a ninth insulation layer 619. For example, the plurality of conductive layers 620 of the multi-layer printed circuit board 600 may include a first conductive layer 621, a second conductive layer 622, a third conductive layer 623, a fourth conductive layer 624, a fifth conductive layer 625, a sixth conductive layer 626, a seventh conductive layer 627, an eighth conductive layer 628, a ninth conductive layer 629, and a tenth conductive layer 630. For example, the multi-layer printed circuit board 600 may be a printed circuit board 600 comprising 10 layers sequentially stacked and disposed including the first conductive layer 621, the first insulation layer 611, the second conductive layer 622, the second insulation layer 612, the third conductive layer 623, the third insulation layer 613, the fourth conductive layer 624, the fourth insulation layer 614, the fifth conductive layer 625, the fifth insulation layer 615, the sixth conductive layer 626, the sixth insulation layer 616, the seventh conductive layer 627, the seventh insulation layer 617, the eighth conductive layer 628, the eighth insulation layer 618, the ninth conductive layer 629, the ninth insulation layer 619, and the tenth conductive layer 630.

According to an embodiment, the plurality of insulation layers 610 of the multi-layer printed circuit board 600 may be any one of the first insulator 310a or the second insulator 310b. According to an embodiment, the type (e.g., the first insulator 310a or the second insulator 310b), the number, and the arrangement of the insulators may be selectively designated according to the thickness required for the printed circuit board. For example, when a thin insulator is required, the first insulator 310a may be disposed. For example, when the insulation layers of the printed circuit board are configured only with the first insulator 310a, warpage may occur or may deteriorate in terms of rigidity, and thus the second insulator 310b including glass fiber may be appropriately disposed. For example, the second insulator 310b may be disposed in at least a portion of a central portion or an edge portion (an upper portion or a lower portion) with respect to the stacking direction (e.g., the Z-axis direction of FIG. 11) to secure rigidity of the printed circuit board 600. For example, the rigidity of the printed circuit board 600 may be about 460,000 (N/m) or more.

According to an embodiment, among the plurality of insulation layers 610 of the multi-layer printed circuit board 600, the insulation layer disposed at the central portion with respect to the stacking direction (e.g., the Z-axis direction of FIG. 11) may be formed of the second insulator 310b. For example, the fifth insulation layer 615 may be formed of the second insulator 310b. According to an embodiment, the configuration of the plurality of insulation layers 610 of the multi-layer printed circuit board 600 may be symmetrically disposed with respect to the insulation layer (e.g., the fifth insulation layer 615 of FIG. 10) disposed at the central portion thereof.

For example, referring to FIG. 11, the fourth insulation layer 614, the fifth insulation layer 615, and the sixth insulation layer 616 may be formed of the second insulator 310b. For example, referring to FIG. 11, the first insulation layer 611, the second insulation layer 612, the third insulation layer 613, the seventh insulation layer 617, the eighth insulation layer 618, and the ninth insulation layer 619 may be formed of the first insulator 310a.

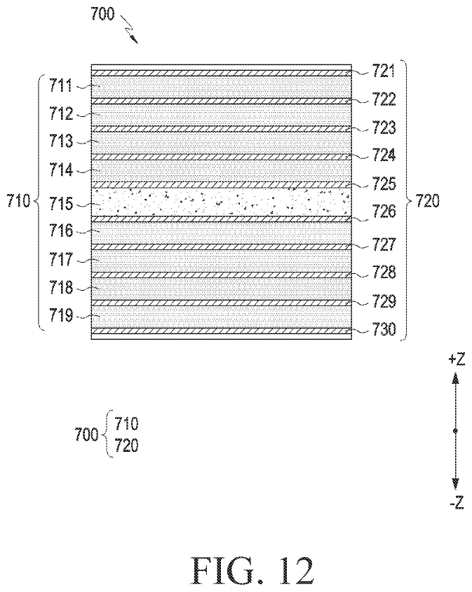

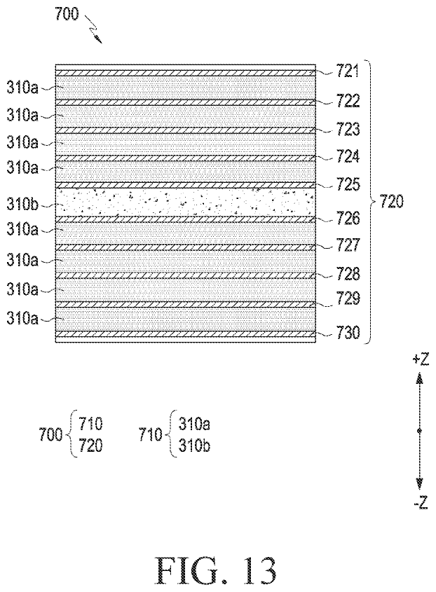

FIGS. 12 and 13 are cross-sectional views of a printed circuit board of FIG. 4A taken along line A-A′ according to various embodiments.

Referring to FIGS. 12 and 13, the electronic device 101 may include a housing (e.g., the housing 201 of FIG. 4) and a printed circuit board 700. The configuration of the printed circuit board 700 of FIGS. 12 and 13 may be identical in whole or part to the configuration of the printed circuit board 300, 500, or 600 of FIGS. 7, 8, 9, 10 and 11 (which may be referred to as FIGS. 7 to 11). The structure of FIGS. 12 and 13 may be selectively combinable with the structures of FIGS. 7 to 11.

According to an embodiment, the multi-layer printed circuit board 700 may include a plurality of layers. Each layer of the multi-layer printed circuit board 700 may include an insulation layer 710 and a conductive layer 720 stacked on the insulation layer 710.

For example, referring to FIGS. 12 and 13, the plurality of insulation layers 710 of the multi-layer printed circuit board 700 may include a first insulation layer 711, a second insulation layer 712, a third insulation layer 713, a fourth insulation layer 714, a fifth insulation layer 715, a sixth insulation layer 716, a seventh insulation layer 717, an eighth insulation layer 718, and a ninth insulation layer 719. For example, the plurality of conductive layers 720 of the multi-layer printed circuit board 700 may include a first conductive layer 721, a second conductive layer 722, a third conductive layer 723, a fourth conductive layer 724, a fifth conductive layer 725, a sixth conductive layer 726, a seventh conductive layer 727, an eighth conductive layer 728, a ninth conductive layer 729, and a tenth conductive layer 730. For example, the multi-layer printed circuit board 700 may be a printed circuit board 700 comprising 10 layers sequentially stacked and disposed including the first conductive layer 721, the first insulation layer 711, the second conductive layer 722, the second insulation layer 712, the third conductive layer 723, the third insulation layer 713, the fourth conductive layer 724, the fourth insulation layer 714, the fifth conductive layer 725, the fifth insulation layer 715, the sixth conductive layer 726, the sixth insulation layer 716, the seventh conductive layer 727, the seventh insulation layer 717, the eighth conductive layer 728, the eighth insulation layer 718, the ninth conductive layer 729, the ninth insulation layer 719, and the tenth conductive layer 730.

According to an embodiment, the plurality of insulation layers 710 of the multi-layer printed circuit board 700 may be any one of the first insulator 310a or the second insulator 310b. According to an embodiment, the type (e.g., the first insulator 310a or the second insulator 310b), the number, and the arrangement of the insulators may be selectively designated according to the thickness required for the printed circuit board. For example, when a thin insulator is required, the first insulator 310a may be disposed. For example, when the insulation layers of the printed circuit board are configured only with the first insulator 310a, warpage may occur or may deteriorate in terms of rigidity, and thus the second insulator 310b including glass fiber may be appropriately disposed. For example, the second insulator 310b may be disposed in at least a portion of a central portion or an edge portion (an upper portion or a lower portion) with respect to the stacking direction (e.g., the Z-axis direction of FIG. 13) to secure rigidity of the printed circuit board 700. For example, the rigidity of the printed circuit board 700 may be about 470,000 (N/m) or more.

According to an embodiment, among the plurality of insulation layers 710 of the multi-layer printed circuit board 700, the insulation layer disposed at the central portion with respect to the stacking direction (e.g., the Z-axis direction of FIG. 13) may be formed of the second insulator 310b. For example, the fifth insulation layer 715 may be formed of the second insulator 310b. According to an embodiment, the configuration of the plurality of insulation layers 710 of the multi-layer printed circuit board 700 may be symmetrically disposed with respect to the insulation layer (e.g., the fifth insulation layer 715 of FIG. 12) disposed at the central portion thereof.

For example, referring to FIG. 13, the fifth insulation layer 715 may be formed of the second insulator 310b. For example, referring to FIG. 13, the first insulation layer 711, the second insulation layer 712, the third insulation layer 713, the fourth insulation layer 714, the sixth insulation layer 716, the seventh insulation layer 717, the eighth insulation layer 718, and the ninth insulation layer 719 may be formed of the first insulator 310a.

According to one embodiment, the plurality of conductive layers may include at least three conductive layers, and the plurality of insulating layers may include at least two insulating layers. For example, the plurality of insulating layers include at least two insulating layers alternately stacked between two of the at least three conductive layers. For example, the embodiments of FIGS. 6 and 7, the embodiments of FIGS. 8 and 9, the embodiments of FIGS. 10 and 11, and the embodiments of FIGS. 12 and 13 all disclose a multi-layer printed circuit board including a number of 10 conductive layers and a number of 9 insulating layer alternately stacked therebetween. However, it should be noted that the present invention is not necessarily limited thereto, and the multilayer printed circuit board may include a larger number of conductive layers and insulating layers, or a smaller number of conductive layers and insulating layers.

An electronic device according to an example embodiment of the disclosure may comprise: a housing and a printed circuit board disposed in the housing and comprising an alternately stacked plurality of insulation layers and a plurality of conductive layers. The plurality of insulation layers may include at least one first insulation layer and at least one second insulation layer. The at least one first insulation layer may include a first insulator including a resin having a glass transition temperature (Tg) value of 200 degrees or more and a filler having a content of 50% to 70%. The at least one second insulation layer may include a second insulator containing glass fiber.

According to an example embodiment, the first insulator may not include glass fiber.

According to an example embodiment, the at least one first insulation layer may have a thickness of 20 μm or less.

According to an example embodiment, a permittivity (Dk) of the first insulator may be 3.0 or less.

According to an example embodiment, a size of the printed circuit board may be 400 mm² or more.

According to an example embodiment, among the plurality of insulation layers, an insulation layer positioned in a center with respect to a stacking direction of the printed circuit board may include the second insulator.

According to an example embodiment, among the plurality of insulation layers, an insulation layer positioned on an upper or lower side with respect to a stacking direction of the printed circuit board may include the second insulator.

According to an example embodiment, a thickness of the at least one second insulation layer may be 25 μm or more.

According to an example embodiment, the printed circuit board may further include at least one via hole penetrating the at least one first insulation layer or the at least one second insulation layer.

According to an example embodiment, a dielectric loss (Df) of the first insulator may be 0.005 or less.

According to an example embodiment, the printed circuit board may have a rigidity of 430,000 (N/m) or more.

According to an example embodiment, the plurality of conductive layers include at least three conductive layers, and the plurality of insulating layers include at least two insulating layers alternately stacked between two of the at least three conductive layers.

An electronic device according to an example embodiment of the disclosure may comprise: a housing and a printed circuit board disposed in the housing and including an alternately stacked plurality of insulation layers and plurality of conductive layers. The plurality of insulation layers may include at least one first insulation layer having a first thickness and at least one second insulation layer having a second thickness greater than the first thickness. The at least one first insulation layer may include a first insulator including a resin having a glass transition temperature (Tg) value of 200 degrees or more and a filler having a content of 50% to 70%. The at least one second insulation layer may include a second insulator including glass fiber.

According to an example embodiment, the first insulator may not include glass fiber.

According to an example embodiment, the at least one first insulation layer may have a thickness of 20 μm or less.

According to an example embodiment, a permittivity (Dk) of the first insulator may be 3.0 or less.

According to an example embodiment, a size of the printed circuit board may be 400 mm² or more.

According to an example embodiment, among the plurality of insulation layers, an insulation layer positioned in a center with respect to a stacking direction of the printed circuit board may include the second insulator.

According to an example embodiment, among the plurality of insulation layers, an insulation layer positioned on an upper or lower side with respect to a stacking direction of the printed circuit board may include the second insulator.

According to an example embodiment, a thickness of the at least one second insulation layer may be 25 μm or more.

According to an example embodiment, a dielectric loss (Df) of the first insulator may be 0.005 or less.

In general, the insulation layer 310 of the printed circuit board 300 may be formed of a prepreg including resin, filler, and glass fiber. As the electronic device is downsized, an ultra-thin insulation layer 310 having a thickness of 20 μm or less is required, but when an ultra-thin insulation layer 310 having a thickness of 20 μm or less is manufactured using a material containing glass, a resin void may be formed as the resin content decreases. When a resin void occurs due to insufficient resin, delamination may occur in the printed circuit board 300. When the thickness of the insulation layer 310 decreases, the dielectric constant value of the insulation layer 310 needs to be decreased for impedance matching. However, since the prepreg includes glass, it may be difficult to decrease the dielectric constant value to 3.0 or less.

The electronic device according to the disclosure may include a printed circuit board 300 including a 20 μm or less-thick first insulator 310a including a resin and a high-content filler, thereby reducing resin voids and presenting a low dielectric constant value.

The printed circuit board according to the disclosure may include a 20 μm or less-thick first insulator 310a comprising a resin having a glass transition temperature (Tg) value of 200 degrees or more and a filler having a content of 50% or more and 70% or less. As the Tg value is high, and the permittivity is low, manufacture at high temperature and impedance matching are rendered possible.

Effects of the disclosure are not limited to the foregoing, and other unmentioned effects would be apparent to one of ordinary skill in the art from the following description.

The electronic device according to embodiments of the disclosure may be one of various types of electronic devices. The electronic devices may include, for example, a portable communication device (e.g., a smartphone), a computer device, a portable multimedia device, a portable medical device, a camera, a wearable device, a home appliance, or the like. According to an embodiment of the disclosure, the electronic devices are not limited to those described above.

An embodiment of the disclosure and terms used therein are not intended to limit the technical features described in the disclosure to specific embodiments, and should be understood to include various modifications, equivalents, or substitutes of the embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), the element may be coupled with the other element directly (e.g., wiredly), wirelessly, or via a third element.

As used herein, the term “module” may include a unit implemented in hardware, software, or firmware, or any combination thereof, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

According to an embodiment, each component (e.g., a module or a program) of the above-described components may include a single entity or multiple entities. Some of the plurality of entities may be separately disposed in different components. According to an embodiment, one or more of the above-described components may be omitted, or one or more other components may be added. Alternatively or Further, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different 5 order or omitted, or one or more other operations may be added.

While the disclosure has been illustrated and described with reference to various example embodiments, it will be understood that the various example embodiments are intended to be illustrative, not limiting. It will be further understood by those skilled in the art that various changes in form and detail may be made without departing from full scope of the disclosure, including the appended claims and their equivalents. It will also be understood that any of the embodiment(s) described herein may be used in conjunction with any other embodiment(s) described herein.

What is claimed is:

1. An electronic device, comprising:
a housing; and
a printed circuit board disposed in the housing and including an alternately stacked plurality of insulation layers and plurality of conductive layers,
wherein the plurality of insulation layers include at least one first insulation layer and at least one second insulation layer,
wherein the at least one first insulation layer includes a first insulator including a resin having a glass transition temperature (Tg) value of 200 degrees or more and a filler having a content of 50% to 70%, and
wherein the at least one second insulation layer includes a second insulator including a glass fiber.

2. The electronic device of claim 1, wherein the first insulator does not include a glass fiber.

3. The electronic device of claim 1, wherein the at least one first insulation layer has a thickness of 20 μm or less.

4. The electronic device of claim 1, wherein a permittivity (Dk) of the first insulator is 3.0 or less.

5. The electronic device of claim 1, wherein a size of the printed circuit board is 400 mm² or more.

6. The electronic device of claim 1, wherein among the plurality of insulation layers, an insulation layer positioned at a center with respect to a stacking direction of the printed circuit board comprises the second insulator.

7. The electronic device of claim 1, wherein among the plurality of insulation layers, an insulation layer positioned at an upper or lower side with respect to a stacking direction of the printed circuit board comprises the second insulator.

8. The electronic device of claim 1, wherein the at least one second insulation layer has a thickness of 20 μm or more.

9. The electronic device of claim 1, wherein the printed circuit board further includes at least one via hole penetrating the at least one first insulation layer or the at least one second insulation layer.

10. The electronic device of claim 1, wherein a dielectric loss (Df) of the first insulator is 0.005 or less.

11. The electronic device of claim 1, wherein the printed circuit board has a rigidity of 430,000 (N/m) or more.

12. The electronic device of claim 1, wherein the plurality of conductive layers include at least three conductive layers, and
wherein the plurality of insulating layers include at least two insulating layers alternately stacked between two of the at least three conductive layers.

13. An electronic device, comprising:
a housing; and
a printed circuit board disposed in the housing and including an alternately stacked plurality of insulation layers and plurality of conductive layers,
wherein the plurality of insulation layers include at least one first insulation layer having a first thickness and at least one second insulation layer having a second thickness greater than the first thickness,
wherein the at least one first insulation layer includes a first insulator including a resin having a glass transition temperature (Tg) value of 200 degrees or more and a filler having a content of 50% to 70%, and
wherein the at least one second insulation layer includes a second insulator including a glass fiber.

14. The electronic device of claim 13, wherein the first insulator does not include the glass fiber.

15. The electronic device of claim 13, wherein the at least one first insulation layer has a thickness of 20 μm or less.

16. The electronic device of claim 13, wherein a permittivity (Dk) of the first insulator is 3.0 or less.

17. The electronic device of claim 13, wherein a size of the printed circuit board is 400 mm² or more.

18. The electronic device of claim 13, wherein among the plurality of insulation layers, an insulation layer positioned at a center with respect to a stacking direction of the printed circuit board comprises the second insulator.

19. The electronic device of claim 13, wherein among the plurality of insulation layers, an insulation layer positioned at an upper or lower side with respect to a stacking direction of the printed circuit board comprises the second insulator.

20. The electronic device of claim 13, wherein the at least one second insulation layer has a thickness of 20 μm or more.
